(19) United States
(12) Patent Application Publication
(10) Pub. No.: US 2007/0077687 A1
(43) Pub. Date: Apr. 5, 2007

(54) METHOD OF PRODUCING CIRCUIT CARRIERS WITH INTEGRATED PASSIVE COMPONENTS

(75) Inventors: Michael Bothe, Ostbevern (DE); Stefan Morbe, Hasbergen (DE)

Correspondence Address: MICHAEL BEST & FRIEDRICH, LLP, 100 E WISCONSIN AVENUE, Suite 3300, MILWAUKEE, WI, 53202, US

(73) Assignee: FRIWO GERATEBAU GMBH, Ostbevern (DE)

(21) Appl. No.: 11/561,261

(22) Filed: Nov. 17, 2006

Related U.S. Application Data
(62) Division of application No. 10/730,374, filed on Dec. 8, 2003.

(30) Foreign Application Priority Data
Jan. 21, 2003 (DE) 10302104.3

(51) Int. Cl. H01L 21/00

(52) U.S. Cl. 438/117

(57) ABSTRACT

The present invention relates to a method for producing an electrical subassembly comprising a circuit carrier and at least one passive component which is integrated into the circuit carrier and comprises an electrically functional material. For providing an improved method for manufacturing an electrical subassembly comprising a circuit carrier and at least one passive component integrated into the circuit carrier, the method ensuring a rapid and inexpensive manufacture on the one hand and permitting a high flexibility on the other hand in the selection of the electrically functional materials involved, the method comprising structuring the circuit carrier, at least one recess being created for the passive element; introducing the electrically functional material in a raw state into the recess of the circuit carrier; converting the electrically functional material from the raw state into a final state by supplying energy.

### RELATED APPLICATIONS

This patent application is a divisional of U.S. patent application Ser. No. 10/730,374 filed Dec. 8, 2003.

### BACKGROUND

1. Field of the Invention

The present invention relates generally to the production of electronic circuits. More particularly, the present invention relates to a method for producing an electrical subassembly comprising a circuit carrier and at least one passive component which is integrated into the circuit carrier and comprises an electrically functional material.

2. Description of the Related Art

In many electronic devices, passive components, such as resistors and capacitors or also inductors, are nowadays needed within a space that is as narrow as possible. Capacitors are e.g. used for suppressing noise, for filtering signals or for storing energy. Different techniques can be used for production. While for reasons of costs wound electrolyte capacitors are still used nowadays for capacitors having high capacitance values, ceramic capacitors are more and more used in filtering applications apart from tantalum capacitors.

Said components have the advantage that they exhibit improved high-frequency characteristics on the one hand and have a small equivalent series resistance on the other hand, also in the case of a high current carrying capacity. To achieve enough capacitance in the case of a small area, said capacitors are often produced by multilayer technique (MLC). This process, however, is very troublesome and entails high costs.

In mains-operated power supplies, capacitors are used for filtering the mains input voltage, the small voltage transmitted to the secondary side, and for suppressing noise on integrated circuits. Ceramic capacitors, in particular, are here of advantage.

With the help of the thick film technology, such circuit structures are realized on a ceramic substrate in which conductor tracks and resistors are integrated. Aluminum oxide is used as the ceramic substrate, which offers the advantage of a high thermal conductivity and of a high insulation resistance. Due to the low dielectric constant of said material (εᵣ is about 9), only a very low capacitance per unit area (<1pF/mm²) can be achieved because the distance of the electrodes cannot be reduced in any desired way on account of the mechanical stability required. A useful integration of capacitances in the order of 1 nF to 100 μF can thus not be achieved.

A further known possibility of producing such ceramic capacitors consists in a configuration by way of a monolayer structure where only one single layer of dielectric material is used. This offers a simple way of production. Moreover, since metallization can be carried out following the firing process, materials with high firing temperatures and thus high dielectric constants Of εᵣ>5000 can be used. Since the panel thickness must be at least 0.2 mm for reasons of mechanical stability, this yields a high dielectric strength. Nevertheless, said stability is normally not sufficient for realizing larger areas and thus higher capacitance values. Due to the monolayer structure, only a low capacitance per unit area (0.1 to 0.2 nF/mm²) is obtained again.

A further possibility of configuration is offered by so-called multilayer components in which many layers (up to 300) of dielectric material are stacked and sintered. Electrodes are positioned between the individual layers. This method yields high capacitance values, the dielectric strength being adjustable through the distance of the individual layers relative to one another. With the same constructional size, a lower capacitance is obtained at a higher dielectric strength, since the layers are thicker. The production of such capacitors, however, is complicated because of the multilayer structure. To be able to use inexpensive materials for the inner electrodes, the firing temperature must be kept low in addition (i.e. below 1000° C.). This, in turn, prevents the use of materials with an extremely high dielectric constant (εᵣ>5000).

To obtain maximum miniaturization, e.g. during use in mains-operated power supplies, such capacitors are of an integrated structure within the circuit carrier proper. An example of a multilayer capacitor which is integrated into the circuit carrier is shown in US patent application US2001/0008479 A1. A multilayer capacitor is formed in a recess of the circuit carrier and is firmly connected to the substrate by subsequent pressing and sintering. In this process a multilayer capacitor is first built up on the lowermost layer of the substrate and embedded by a structured second layer of the substrate and covered by a cover layer. This method has the drawback that it is relatively complicated because the multilayer capacitor must be structured separately and in addition to the structuring of the substrate layers.

### SUMMARY OF THE INVENTION

It is therefore the object of the present invention to provide an improved method for producing an electrical subassembly with a circuit carrier and at least one passive component integrated into the circuit carrier, which ensures a rapid and inexpensive manufacture on the one hand and a high flexibility in the selection of the electrically functional materials involved on the other hand.

Said object is achieved by a method comprising the features of patent claim 1.

Advantageous developments of the invention are described in the dependent claims.

The invention is based on the finding that the manufacturing process of such a subassembly can be simplified considerably if recesses or cavities provided in the circuit carrier are used for structuring the electrically functional material in a raw state, e.g. in the form of precursor material such as a non-cured paste. Passive components, such as capacitors and ohmic resistors, but also inductors, can be produced thereby in a particularly efficient and area-saving way. Moreover, capacitors can be produced with different capacitances and/or resistors with different conductivities, and also diverse inductors, in one fabrication step and at low costs.

According to an advantageous embodiment of the present invention, energy is supplied by exerting a mechanical pressure. Of particular advantage is here that, when ceramic circuit carriers are used, such a pressing step for solidifying the electrically functional material can be carried out simultaneously with a pressing step for solidifying the circuit carrier.

In addition, or as an alternative, to a conversion by pressing, energy can also be supplied by way of a heat supply. Individual constituents of the electrically functional material can be melted in the raw state, and a firm connection to the circuit carrier or also to electrically conductive terminals can be established.

The advantageous characteristics of the method of the invention are particularly felt whenever the passive component is a capacitor. The electrically functional feature is then a dielectric, e.g. a ceramic material.

Alternatively, or in addition, the passive component may also be a resistor. In this case a substance with an exactly defined electrical conductivity, as is e.g. known from thick film technology, is used as an electrically functional material. The manufacturing method according to the invention also offers the advantage in this context that very different resistance values can be obtained in a particularly efficient way. Moreover, a multitude of different capacitors and resistors can be realized on a circuit carrier. To be able to observe sufficiently narrow tolerances in the manufacture of integrated resistors, a trimming step, e.g. laser trimming, may be provided.

The electrically functional material may e.g. be present in the form of a paste in the raw state. The wiping of said paste into corresponding recesses of the circuit carrier will then constitute a particularly efficient solution that can be automated easily.

Alternatively, the electrically functional material can be pressed in its raw state into the recesses as well. A particularly gapless and uniform filling of even the smallest structures can thus be ensured.

For electrically contacting the integrated passive component, at least one conductor track structure can be produced. This step is either performed before the insertion of the electrically functional material in the raw state or thereafter and during contacting at both sides before and after insertion.

The recesses needed in the circuit carrier can be produced in a multitude of shaping methods, depending on the materials used and the geometrical structures needed. Said recesses can be made in a particularly simple way by machining the solid material of the circuit carrier. Especially with small series where only small numbers of pieces are to be produced, this may be an inexpensive variant. Alternatively, stamping methods can of course be used, as are generally known in ceramic technology.

The structuring of the circuit carrier, however, can be carried out by forming at least one first layer acting as a carrier layer, by forming at least one second layer in which openings are arranged, and by subsequently joining the first and second layers to form a circuit carrier. This structuring method, which is also wide-spread in ceramic technology, offers the advantage that it does not need any application-specific tools and can be automated to a large extent. For instance, when the first and second layers are both made of ceramics, the step of joining includes pressing and firing of the ceramic material. A multitude of structures can thus be produced in an inexpensive and simple way.

Alternatively, the second layer may also be formed by metallization. This offers the advantage that a subsequent pressing and/or sintering step is no longer needed. The structuring of metallizations is a wide-spread and easily governable technological step in the manufacture of printed circuit boards.

If one wishes to expose the integrated passive components after the manufacturing process, the method according to the invention may comprise, as the final step, the step of removing at least part of the second layer.

### BRIEF DESCRIPTION OF THE DRAWINGS

The accompanying drawings are incorporated into and form a part of the specification for the purpose of explaining the principles of the invention. The drawings are not to be construed as limiting the invention to only the illustrated and described examples of how the invention can be made and used. Further features and advantages will become apparent from the following and more particular description of the invention as illustrated in the accompanying drawings, wherein:

FIG. 1 is a schematic sectional view showing a circuit carrier formed from two layers;

FIG. 2 shows the circuit carrier of FIG. 1 after application of a metallization layer;

FIG. 3 shows the circuit carrier of FIG. 2 after joining the layers by stacking;

FIG. 4 shows the circuit carrier of FIG. 3 after insertion of a dielectric in the raw state;

FIG. 5 shows the circuit carrier of FIG. 4 after insertion of a further metallization layer;

FIG. 6 shows the pressing and firing of the circuit carrier of FIG. 5 in a schematic illustration;

FIG. 7 shows a circuit carrier according to a second embodiment;

FIG. 8 shows the circuit carrier of FIG. 7 after stacking;

FIG. 9 is a schematic illustration showing the pressing and firing process for forming a sintered circuit carrier;

FIG. 10 shows the circuit carrier of FIG. 9 after application of a closed metallization layer;

FIG. 11 shows the circuit carrier of FIG. 10 after partial removal of the metallization layer;

FIG. 12 shows the circuit carrier of FIG. 11 after insertion of a dielectric;

FIG. 13 is a schematic illustration showing the pressing and firing operation of the circuit carrier of FIG. 12;

FIG. 14 shows the circuit carrier of FIG. 13 after application of an overall metallization;

FIG. 15 is a schematic illustration of the finished subassembly after structuring of the second metallization layer;

FIG. 16 is a schematic sectional view through a ceramic base plate with an opening for later vias;

FIG. 17 shows the base plate of FIG. 17 after complete coating with a copper layer;

FIG. 18 shows the base plate of FIG. 17 after application of a further copper layer;

FIG. 19 shows the structure of FIG. 18 after structuring the metal layer;

FIG. 20 shows the structure of FIG. 19 after introduction of a dielectric pre-stage into the recesses formed in the metal;

FIG. 21 is a schematic illustration of a pressing and firing operation for solidifying the dielectric;

FIG. 22 shows the structure of FIG. 21 after application of a further copper layer;

FIG. 23 shows the circuit carrier in the final state after partial removal of the copper metallization;

FIG. 24 is a schematic sectional view of a circuit carrier made of ceramics during pressing and firing;

FIG. 25 shows the circuit carrier of FIG. 24 after structuring;

FIG. 26 shows the structured circuit carrier of FIG. 25 after application of an overall metallization;

FIG. 27 shows the circuit carrier of FIG. 26 after structuring of the metallization;

FIG. 28 shows the circuit carrier of FIG. 27 after insertion of the dielectric in the raw state;

FIG. 29 is a schematic illustration of the pressing and firing operation for solidifying the dielectric;

FIG. 30 shows the circuit carrier of FIG. 29 after application of an overall second metallization;

FIG. 31 shows the circuit carrier in the final state after structuring of the second metallization layer.

### DETAILED DESCRIPTION OF THE INVENTION

The illustrated embodiments of the present invention will be described with reference to the figure drawings, wherein like elements and structures are indicated by a like reference numbers.

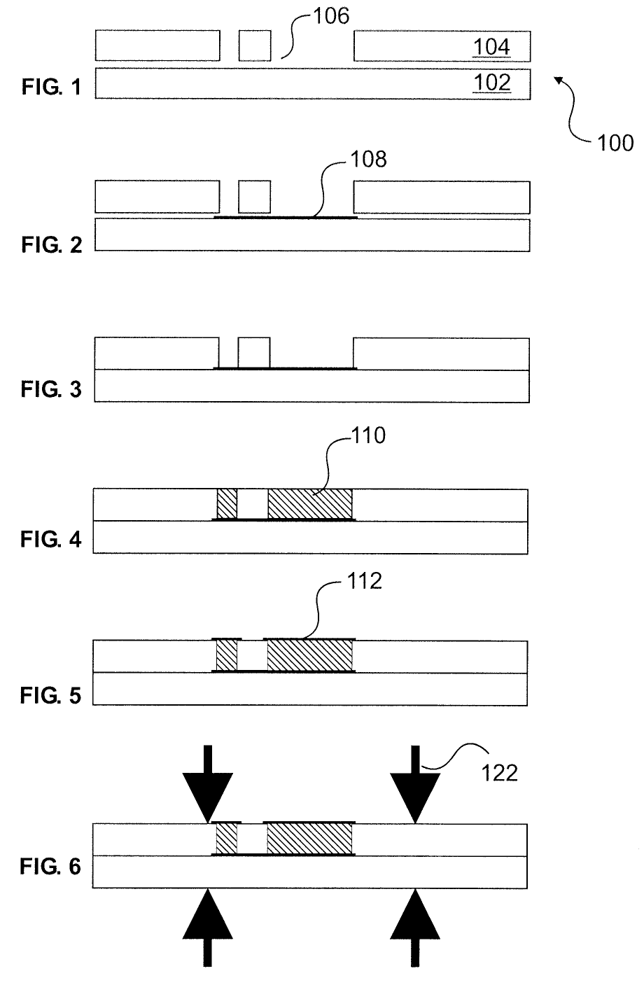

With reference to FIGS. 1 to 6 the manufacturing method according to the invention shall now be explained in more detail with reference to a first embodiment.

In the method according to the first embodiment a subassembly is produced with different integrated capacitors and a circuit carrier of ceramics. The ceramic substrates can provide great heat dissipation. They are structured and metallized such that free spaces are created for a dielectric substance in the raw state. This substance is introduced into the free spaces and the stacked ceramic substrates are pressed and sintered. The dielectric can be contacted from both sides. FIG. 1 shows a first ceramic layer 102 and a second ceramic layer 104 before these are joined to form a circuit carrier 100. The first ceramic layer 102 serves as a base layer and the second ceramic layer 104 is structured such that recesses 106 are created for later introduction of the dielectric.

As can be seen from FIG. 2, for contacting the later capacitors, a first metallization layer 108 is applied to the first ceramic layer 102 and structured.

FIG. 3 shows the circuit carrier 100 after stacking the ceramic layers 102 and 104.

In a next step (see FIG. 4), a dielectric 110 is introduced in a raw state into the recesses 106. This can e.g. be done by pressing in or wiping a paste.

As shown in FIG. 5, a second metallization layer 112 can be applied and structured for electrically contacting the later capacitors at both sides. Both the individual ceramic layers 102, 104 and the dielectric 112 are solidified by the subsequent pressing and firing operation, symbolized by arrows 122 in FIG. 6, and converted into the final state.

Although two capacitors are produced as integrated passive components in FIGS. 1 to 6, any desired number of passive components can of course be realized in the circuit carrier, and conductive materials of a defined conductivity can also be introduced at the same time as, or as an alternative to, the dielectric for forming integrated resistors. A trimming process may be needed for observing the tolerances required in integrated resistors. The production of integrated inductors is also possible.

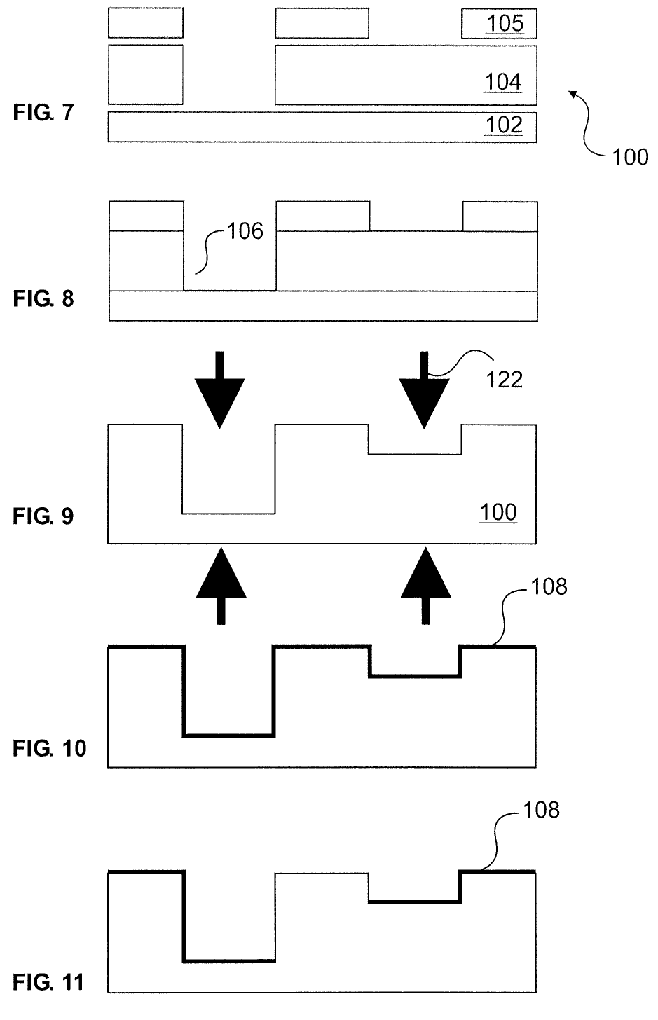

FIGS. 7 to 15 explain a method according to a second embodiment with the help of which passive components of a different thickness can also be produced.

First of all, as shown in FIGS. 7 to 9, a ceramic substrate 100 is produced by the measure that individual ceramic layers 102, 104, and 105 are structured, stacked and pressed and fired.

Said ceramic substrate 100 is fully metallized on the structured side, the metallization 108 is structured by photo-structured etching or in a process similar to the damascene method (FIGS. 10 and 11).

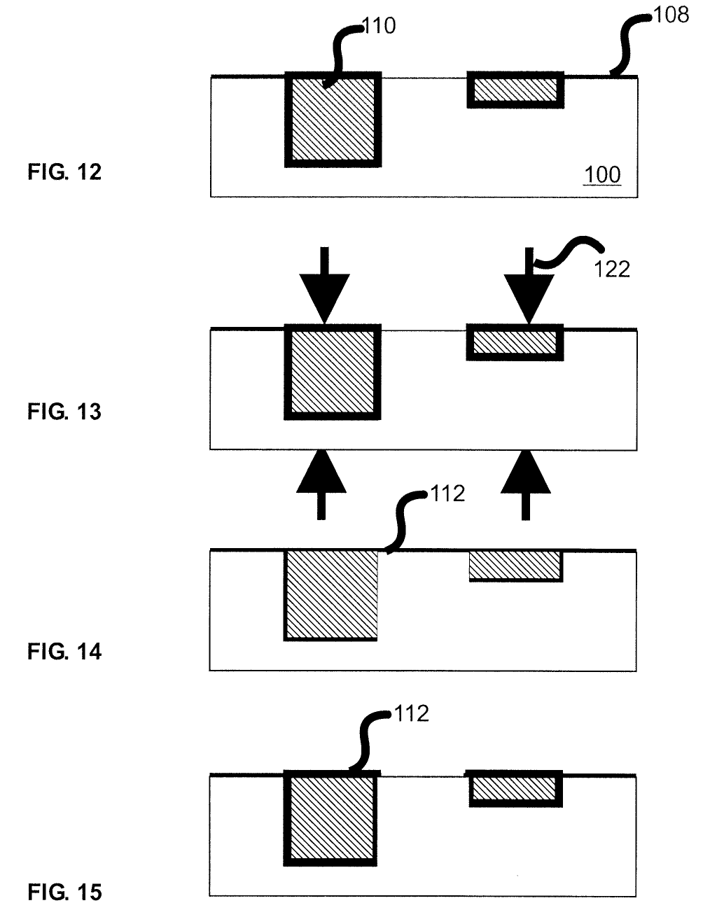

The dielectric 112 is then introduced in the raw state into the free spaces 106 provided for (FIG. 12). A second firing operation is carried out, shown by symbols in FIG. 13. Subsequently, the still missing contact surfaces are produced by a second metallization layer 112 to be structured (FIGS. 14 and 15).

The first firing operation for the substrate can take place at an elevated temperature because no metals are here needed. Therefore, said first firing operation can be optimized with respect to the desired properties of the ceramic substrate. The second firing process for the dielectric 112 can also take place at low temperatures (below 1000° C.) when suitable materials have been chosen. In such a case it is also possible to use more low-melting and inexpensive metals (e.g. silver).

In the method according to this second embodiment, resistor components or inductors can be realized apart from the capacitors shown.

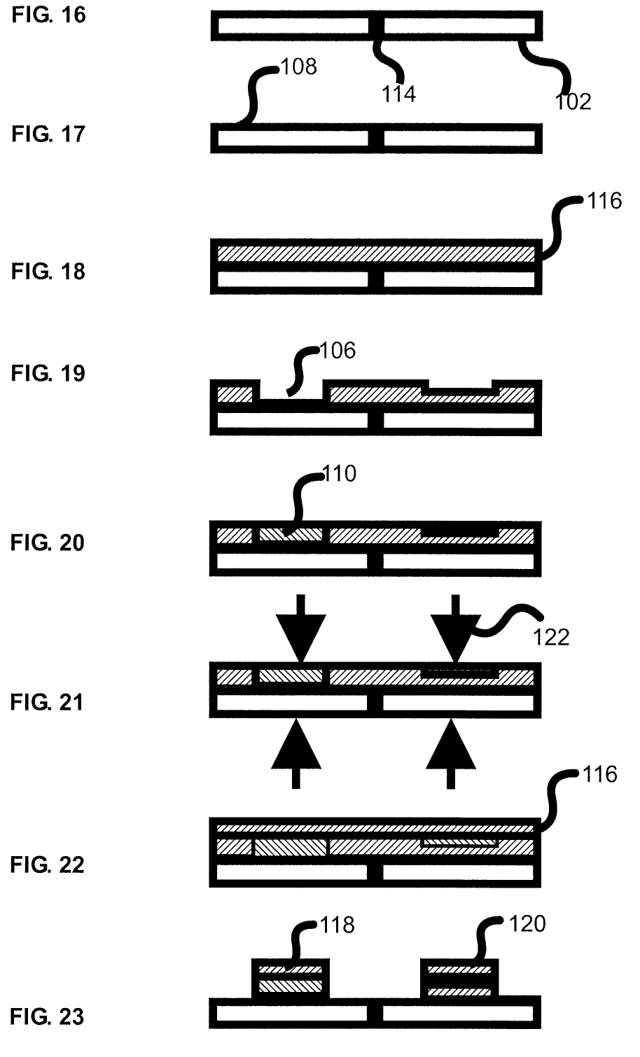

A third variant of the manufacturing method according to the invention shall now be explained with reference to FIGS. 16 to 23.

As a starting structure, a first ceramic layer 102 is provided with corresponding vias 114 (FIG. 16).

FIG. 17 shows the next step in which the first ceramic layer 102 is completely covered with a copper layer 108. The vias 114 are also metallized in this case.

As shown in FIG. 18, a continuous and relatively thick metal layer, preferably a copper layer 116, is subsequently applied. The copper layer 116 is e.g. structured by etching such that free spaces 106 are created for the dielectric (FIG. 19).

FIG. 20 shows the structure of FIG. 19 after introduction of the dielectric 110. Said dielectric is in a raw state and, as outlined in FIG. 21, is converted by a pressing and firing operation into a final state.

As shown in FIG. 22, the second contacting of the capacitors is prepared by a repeated metallization step.

As outlined in FIG. 23, the metallization 116 is removed in a final etching step to such an extent that the capacitors 118 and 120 are isolated from one another.

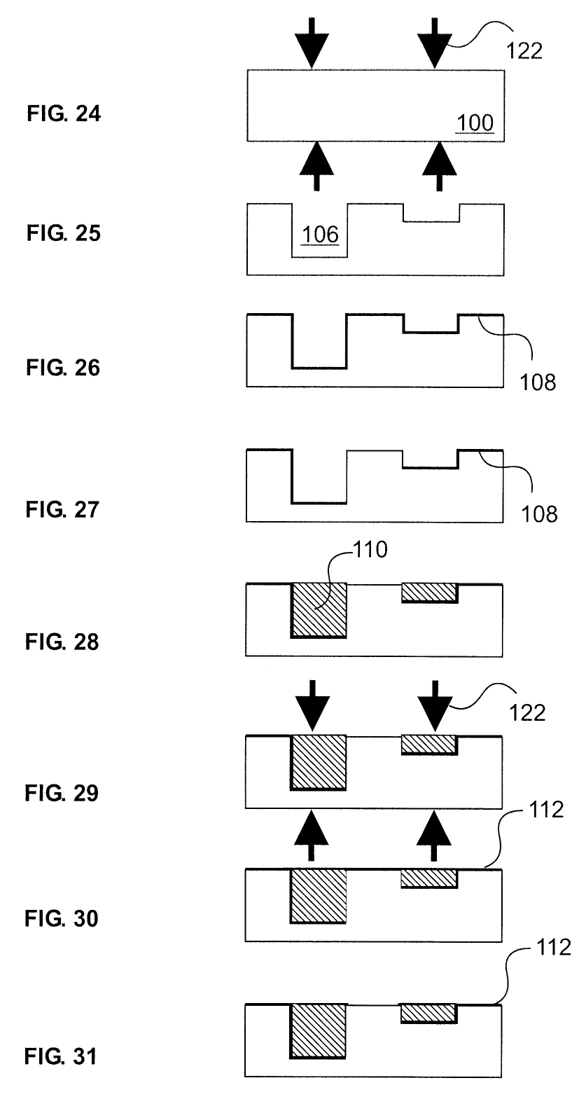

A fourth embodiment of the method according to the invention is shown in FIGS. 24 to 31.

A pressing and firing operation of the ceramic substrate 100 is first of all performed (FIG. 24). As shown in FIG. 25, the ceramic is structured “from the solid block”, e.g. by milling or a laser treatment. By analogy with the process steps of FIGS. 10 to 15, the steps metallization, structuring of the metallization, introduction of the dielectric and a further pressing and firing operation are then performed (FIGS. 26 through 29). The missing contacts have now to be metallized again. This can be done either with the help of a mask by a photo technique, first with a complete metallization and a subsequent etching operation or by means of a damascene technique.

In all of the illustrated embodiments of the manufacturing process according to the invention, silver palladium or another conductive material with a melting temperature of more than 1300° C. can be used for the first metallization 108 and/or for the second metallization 112. The dielectric should have a comparatively high dielectric constant in its final state. For instance, a capacitance range of about 1 nF to 1000 nF with a dielectric strength of 400 V and a capacitance range of 10 nF to 100 μF with a dielectric strength of 10 V are desirable for mains-operated power supplies.

When the firing operation is carried out in two stages, the first stage can be carried out with a high temperature when no metals with an excessively low melting point are involved, and the second stage can be carried out at a lower temperature. Capacitors which have dielectrics with mean dielectric constants (εᵣ>1000) are e.g. fired at a temperature of 900° C. in a nitrogen atmosphere. Capacitors of materials having high dielectric constants (εᵣ>5000) must be fired at a temperature of 1300° C.

A high thermal conductivity is achieved by using ceramics as circuit carriers. The dielectric strength can be adjusted by way of different layer thicknesses or different numbers of layers. With the help of the manufacturing method of the invention, it is possible to produce circuit carriers based on ceramics with integrated resistive, capacitive and/or inductive components at low costs, and a significant miniaturization of the whole subassembly can be achieved by integration.

While the invention has been described with respect to the physical embodiments in accordance therewith, it will be apparent to those skilled in the art that various modifications, variations and improvements of the present invention may be made in the light of the above teachings and within the purview of the appended claims without departing from the spirit and intended scope of the invention.

In addition, those areas in which it is believed that those ordinary skilled in the art are familiar have not been described herein in order not to unnecessarily obscure the invention described herein.

Accordingly, it is to be understood that the invention is not to be limited by the specific illustrated embodiments, but only by the scope of the appended claims.

What is claimed is:

1. A method for producing an electrical subassembly with a circuit carrier and a plurality of passive components being integrated into the circuit carrier and comprising an electrically functional material, wherein at least one of the passive components is a capacitor with a dielectric as an electrically functional material, the method comprising the following steps:
structuring the circuit carrier, a plurality of recesses being created for said passive components, said recesses having at least two different depths;
introducing the electrically functional material in a raw state into the recesses of said circuit carrier;
converting said electrically functional material from said raw state into a final state by supplying exerting mechanical pressure and/or supplying heat.

2. The method according to claim 1, wherein at least one of the passive components is a resistor, said electrically functional material in the raw state being a paste having a given specific resistance.

3. The method according to claim 1, wherein the step of introducing said electrically functional material in the raw state into the recess of said circuit carrier comprises the wiping of a paste.

4. The method according to claim 1, wherein the step of introducing said electrically functional material in the raw state into the recess of said circuit carrier comprises the pressing in of a paste.

5. The method according to claim 1, further comprising the following step:
forming at least one conductor track structure for electrically contacting the electrically functional material.

6. The method according to claim 1, wherein the step of structuring the circuit carrier comprises producing the plurality of recesses by machining.

7. The method according to claim 1, wherein the step of structuring said circuit carrier comprises:
forming at least one first layer;
forming at least one second layer having openings arranged therein;
joining said first and second layers to obtain said circuit carrier so that said recesses are formed by said openings.

8. The method according to claim 7, wherein said first and second layers are made from ceramics and the step of joining comprises the pressing and firing of said ceramics.

9. The method according to claim 7, wherein said first layer can be made from an electrically insulating material and said second layer is formed by metallization.

10. The method according to claim 9, further comprising the following step: removing at least part of said second layer for exposing said passive component.
